(19) United States
(12) Patent Application Publication
(10) Pub. No.: US 2004/0261714 A1
(43) Pub. Date: Dec. 30, 2004

(54) Plasma processing apparatus

(76) Inventor: Min-Woong Choi, Gyeonggi-do (KR)

Correspondence Address: MARGER JOHNSON & McCOLLOM, P.C., 1030 S.W. Morrison Street, Portland, OR, 97205, US

(21) Appl. No.: 10/868,255

(22) Filed: Jun. 14, 2004

(30) Foreign Application Priority Data
Jun. 26, 2003 (KR) 2003-42170

(51) Int. Cl. C23C 16/00

(52) U.S. Cl. 118/723 E

(57) ABSTRACT

An apparatus is provided. The apparatus comprises a chamber for loading a substrate therein, a plasma creation area in the chamber, first and second electrodes installed in the chamber, and a power source for supplying a radio frequency to the first electrode. The first electrode includes a plurality of areas having different resistances for varying the radio frequency applied to the plasma creation area. The upper electrode makes a plasma density uniform to enhance a process uniformity.

This application claims priority from Korean Patent Application No. 2003-42170, filed on Jun. 26, 2003, the contents of which are incorporated herein by reference in their entirety.

### FIELD OF THE INVENTION

The present invention relates to a semiconductor fabrication apparatus, for example, a plasma processing apparatus and, more particularly, to a plasma processing apparatus having a modified upper electrode.

### BACKGROUND OF THE INVENTION

Generally, a semiconductor device is fabricated by depositing a predetermined layer(s) onto a substrate and etching the deposited layer(s) to form a pattern. With the recent trend toward finer semiconductor devices, etch techniques have advanced from a wet etch technique to a dry etch technique.

The construction of a plasma-etching apparatus is illustrated in FIG. 5. An etch chamber 10 has an upper electrode 12 and a lower electrode 14. Power in the form of a radio frequency wave is supplied to these electrodes 12 and 14 to produce a plasma 20. The radio frequency wave supplied from radio frequency wave suppliers 22 and 24 is applied to the upper and lower electrodes 12 and 14 through a matchbox. Plasma constituents, such as ions, radicals, and electrons, are introduced to the lower electrode 14 by an electromagnetic force. A substrate W is placed on the lower electrode 14 to be etched by the plasma gas.

A pumping system (not shown) is provided to keep a high vacuum state in the etch chamber 10 during an etch process. The pumping system is placed at a lower position of the etch chamber 10. Polymer and etch byproducts produced during the etch process may be absorbed by the substrate creating a particle source. The pumping system prevents the creation of the particle source.

Arrows of FIG. 5 show the flow of the plasma gas. The pumping system is disposed at the lower position of the etch chamber 10, so that the plasma gas is rapidly pumped down from the edge of the substrate W. This is because the power of the radio frequency wave, which is supplied to the lower electrode 14 on which the substrate W is disposed, is equivalent at the center and the edge of the lower electrode 14 but a pumping pressure is higher at the outer portion of the lower electrode 14.

In this connection, the flux of the plasma gas during the etch process is not uniform at the surface of the substrate W which is disposed on a top surface of the lower electrode 14. Since the flux of the plasma gas is moved from the edge of the substrate W to the outside portion thereof, the etch rate at the center of the substrate W is higher than that at the edge of the substrate W.

Due to the above characteristics, the etch rate and surface uniformity are different between the center and edge of the substrate W. Further, this problem is intensified as a substrate size becomes larger.

### SUMMARY OF THE INVENTION

According to one embodiment of the present invention, an apparatus comprises a chamber for loading a substrate therein, a plasma creation area in the chamber, first and second electrodes installed in the chamber, and a power source for supplying a radio frequency to the first electrode. The first electrode includes a plurality of areas having different resistances for varying the radio frequency applied to the plasma creation area. The upper electrode makes a plasma density uniform to enhance a process uniformity.

### BRIEF DESCRIPTION OF THE DRAWINGS

FIG. 1 is a cross-sectional view of a plasma processing apparatus according to the present invention.

FIG. 2 through FIG. 4 are diagrams for explaining electrode plates each having a different internal resistance.

FIG. 5 is a schematic diagram of a typical dry etch apparatus.

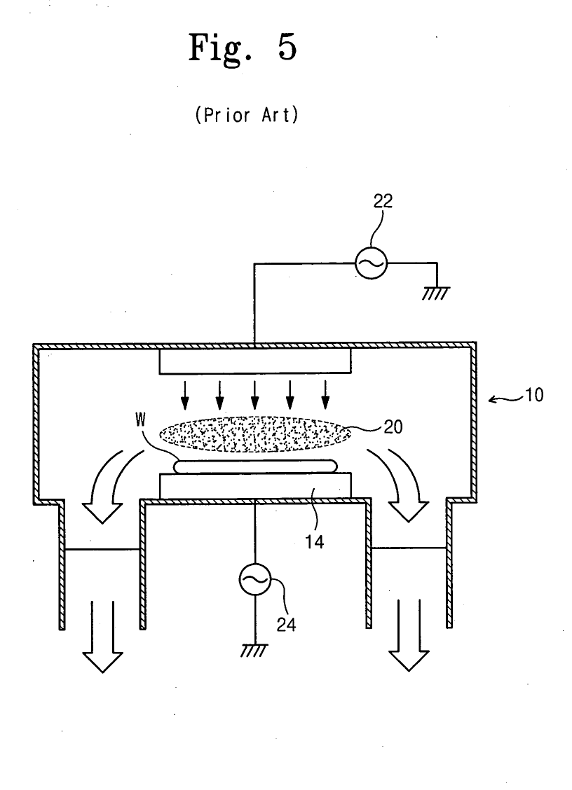

### DESCRIPTION OF THE PREFERRED EMBODIMENT

Hereinafter, the present invention will be described more fully with reference to the accompanying drawings in which preferred embodiment of the invention are shown. This invention may, however, be embodied in many different forms and should not be construed as being limited to the embodiments set forth herein, rather, these embodiments are provided so that this disclosure is thorough and complete, and fully conveys the concept of the invention to those skilled in the art. In the drawings, the thickness of layers and regions are exaggerated for clarity. To facilitate understanding, identical reference numerals have been used, where possible, to designate identical elements that are common to the figures.

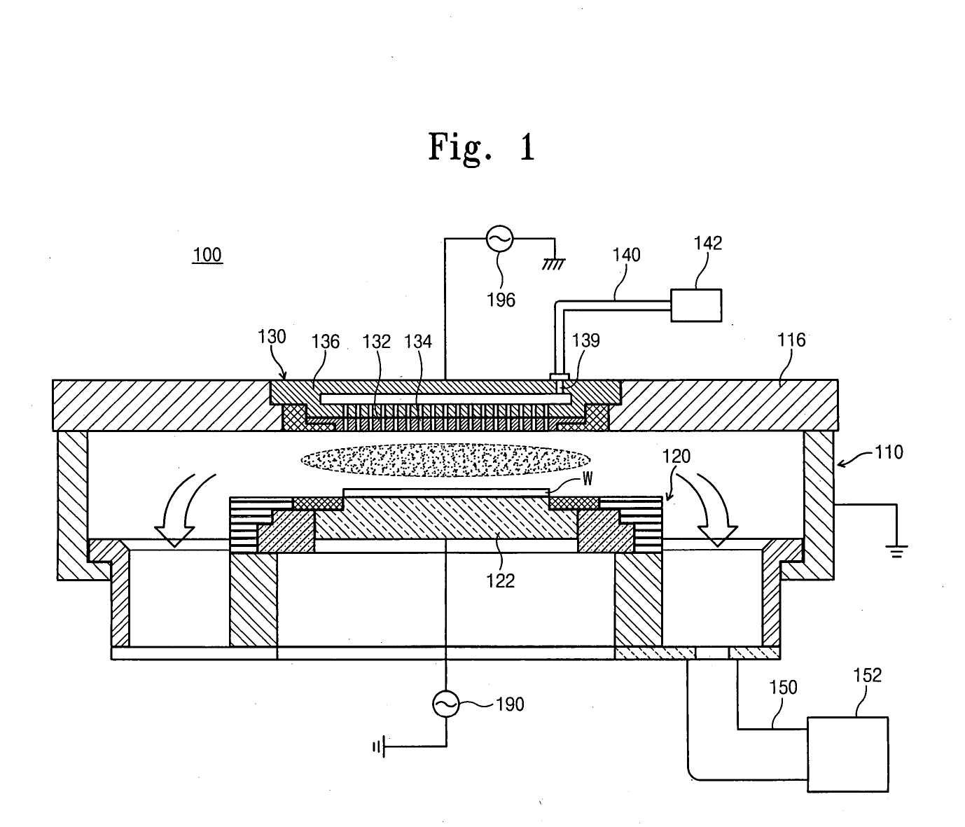

Referring to FIG. 1, a plasma processing apparatus 100 includes a parallel plate etching device having an upper electrode plate and a lower electrode plate. The upper and lower plates are disposed opposite to each other. The power for creating a plasma is connected to one of the electrodes, and the power for extracting ions is connected to the other.

The plasma processing apparatus 100 has a cylindrical chamber 110 that is made of, for example, aluminum, whose surface may be alumite-treated (bipolar-oxidized). The chamber 110 is safety-grounded. An exhaust pipe 150 is connected to a bottom of the chamber 110. An exhaust unit 152 is connected to the exhaust pipe 150 and has a vacuum pump such as a turbo-molecular pump to vacuum the inside of the chamber 110, e.g., at a predetermined pressure of about 0.1 mTorr or less, and to transport the vacuumed material from the chamber 110.

A columnar susceptor 120 is installed at the bottom in the chamber 110. A substrate W is placed on the susceptor 120. The susceptor 120 includes an electrostatic chuck 122 having substantially the same shape as the substrate W. A second radio frequency (RF) power source 190 is connected to the susceptor 120 and acts as a lower electrode. The second RF power source 190 introduces ions into the substrate W and applies a suitable ion reaction to the substrate. The frequency of the second RF power source 190 can be, for example, about 2 MHz.

An upper electrode 130 is installed over the susceptor 120. The electrode 130 and the susceptor 120 are disposed in a parallel plane and located opposite to each other.

The upper electrode 130 is supported at the upper portion of the chamber 110. The outer portion of upper electrode 130 comprises an insulation material 116 which is maintained on chamber 110. The insulation material 116 is located opposite to the susceptor 120. A plurality of openings 134 are formed within the upper electrode 130. The upper electrode 130 has an electrode plate 132, and a water-cooled electrode supporter 136 for supporting the electrode plate 132. The electrode plate 132 is typically made of silicon, SiC or amorphous carbon. The surface of the electrode supporter 136 is preferably made of alumite-treated aluminum. The susceptor 120 and the upper electrode 130 are spaced apart from each other. The spaced apart distance therebetween can be, for example, about 10-60 mm.

A gas introduction orifice 139 is formed in the electrode supporter 136 of the upper electrode 130. A gas supply pipe 140 is connected to the gas introduction orifice 139. A treatment gas source 142 is connected to the gas supply pipe 140. A treatment gas for plasma etching is supplied from the treatment gas source 142. The treatment gas is typically a halogen-containing gas such as, for example, a fluorocarbon gas (CₓF_{y}) or a hydrofluorocarbon gas (CₓH_{y}F_{z}). Further, an inert gas such as Ar or He or N₂ may be added to the treatment gas.

A first RF power source 196, which can have a frequency of 60 MHz or higher, is connected to the electrode supporter 136. A high frequency can be applied to create high-density plasma, and the plasma treatment may be carried out under a low pressure of 10 mTorr or lower. Therefore, under the conditions described above, it is possible to comply with a finer design rule.

The electrode plate 132 has a central area and an edge area, respectively, which have different internal resistances to change the applied rate of the RF which is applied within the plasma formation area. In order to make the internal resistances of the electrode plate 132 dissimilar, ions are implanted in a manner which will make the resistances at each area different. Furthermore, the electrode plate 132 may include at least one intermediate area disposed between the central area and the edge area to facilitate the positioning of the different resistances.

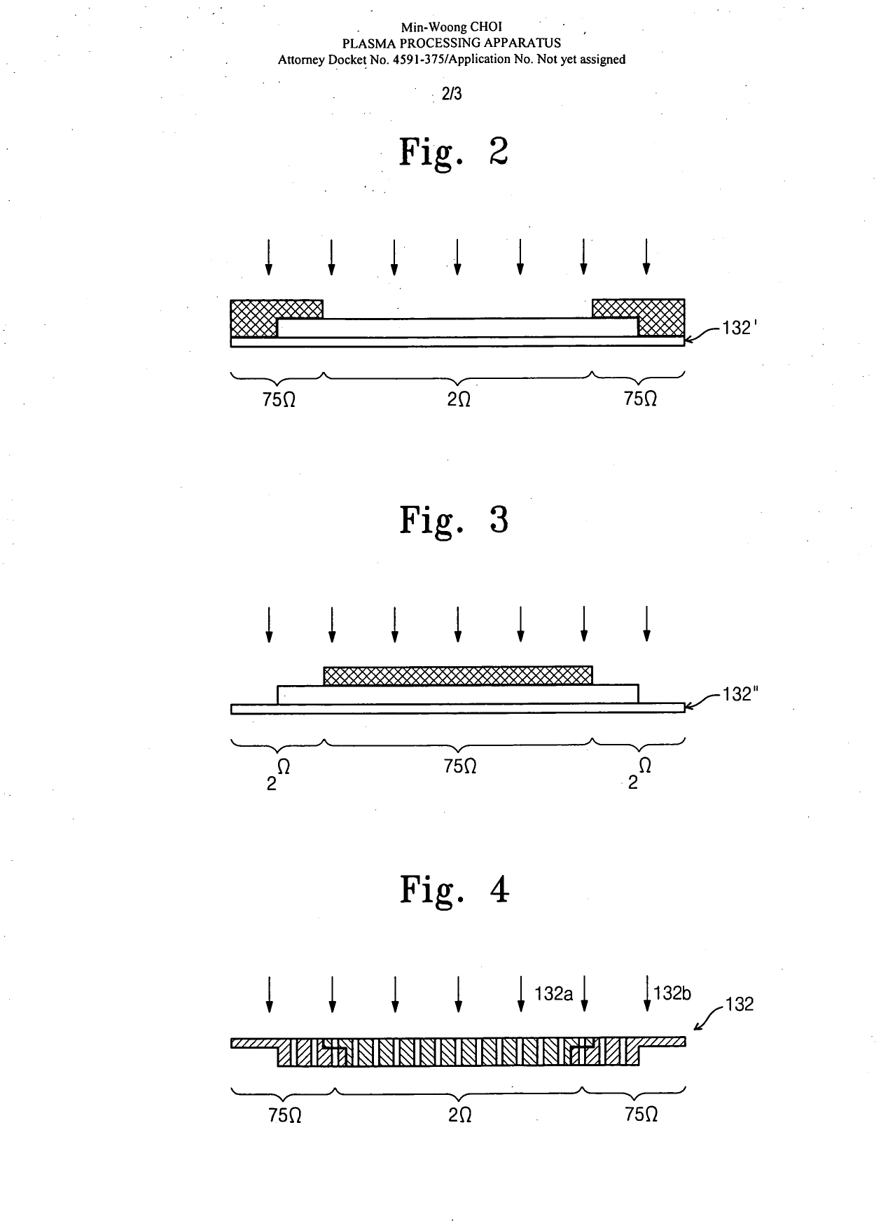

As shown in FIG. 2 and FIG. 3, the internal resistance values can be altered by manufacturing an ingot with a 75 Ω resistance as a plate, and then implanting ions into the plate to form the areas having the different resistances. This ion implantation typically employs a similar technique as are employed with the ions which are implanted into the substrate.

For example, if the etch rate of the edge area of the substrate is higher than that of the central area of the substrate, a process is preferably performed using an electrode plate where an internal resistance (such as 2 Ω) in the central area is lower than the internal resistance (such as 75 Ω) of the edge area. Thus, since the RF applied rate in the central area of electrode plate 132′ is relatively higher than that of that in the edge area of the electrode plate 132′, the etch rate in the central area of the substrate W may be more enhanced than an etch rate in the edge area thereof. Such an electrode plate 132′ may be fabricated by masking the edge area using a photoresist (PR), and then implanting ions into a central area, as shown in FIG. 2.

On the other hand, in the case where an etch rate of the edge area of the substrate W is lower than that of the central area of the substrate, it is preferable to use an electrode plate where the internal resistance (such as 2 Ω) of the edge area is higher than an internal resistance (such as 75 Ω) of the central area. Since an RF applied rate in the central area of such an electrode plate 132″ is relatively lower than that of the edge area of such an electrode plate 132″, the etch rate in the edge area of the substrate may be more enhanced than an etch rate of the edge area thereof. Such an electrode plate 132″ may be fabricated by masking the center area using a photoresist (PR) then only implanting ions into the edge area.

As described above, in a plate constituting an electrode plate, the different amount of ions which are implanted into the respective areas of the plate make the internal resistances of the respective areas different.

Instead of employing the ion implanting method described above, as shown in FIG. 4, an electrode plate 132 may be used including a central plate 132a and an edge plate 132b which have different internal resistances.

As described above, the upper electrode may be designed to be suitable for the specified structure of a given apparatus, or an apparatus having specified process characteristics, or a specified process for fabricating parts. Generally, the structure of an electrode is designed according to a specified material of construction, or a specified chamber structure, or a specified method of construction, or a specified plasma regime. Further, if the number of openings formed in the upper electrode and the construction manner of the upper electrode are determined, the upper electrode is optimally fabricated by various known fabricating processes. Undoubtedly, the cost of a fabricating company must be considered.

As previously emphasized, a main effect of the present invention is to enhance process capability. The upper electrode results in a difference between RF applied rates at the central and the edge areas of a plasma creation area due to a difference between internal resistances of the electrode plate at these different locations. The RF applied rate difference causes an alteration of plasma density. For this reason, in the event that an upper electrode has resistances which are different at respective regions, the etch rate and the etch selectivity can be substantially enhanced. Particularly, it is possible to control the etch rate difference and the uniformity difference in the central and the edge areas of a substrate.

The principles of the present invention can be applied to a dry etcher such as an oxide processing apparatus manufactured by the LAM Corporation Fremont, Calif. (particularly, etchers called “EXELAN” and “RAINBOW” using a silicon electrode). Further, the plasma processing apparatus can be applied to an oxide processing apparatus such as the SCCM MODEL equipment manufactured by the TEL corporation.

The electrode plate may be made of high-purity SiC (e.g., sintered SiC, reactive SiC, reactive sintered SiC, etc.) because of the properties of these various products.

From the foregoing, it will be observed that numerous variations and modifications may be effected without departing from the spirit and scope of the invention. It is to be understood that no limitation with respect to the specific apparatus illustrated herein is intended or should be inferred. It is, of course, intended to cover by the appended claims all such modifications as fall within the scope of the claims.

What is claimed is:

1. An apparatus comprising:
a chamber for loading a substrate therein;
first and second electrodes installed in the chamber, the first and second electrodes being disposed opposite to each other; and
a power source for supplying a radio frequency to the first electrode,
wherein the first electrode includes a plurality of areas having different resistances.

2. The plasma processing apparatus of claim 1, wherein the plurality of areas comprise a central area and an edge area, and the respective central area and edge areas have different internal resistance values.

3. The plasma processing apparatus of claim 2, wherein the resistance value of the central area is lower than that of the edge area.

4. The plasma processing apparatus of claim 2, wherein the first electrode further includes at least one intermediate area interposed between the central area and the edge area, and the respective central area, edge area, and intermediate area have different internal resistance values.

5. The plasma processing apparatus of claim 1, wherein the first electrode forms said different resistances at the respective areas by implanting a different amount of ions into the respective areas.

6. The plasma processing apparatus of claim 5, wherein the first electrode has a central area and an edge area, and the respective central area and edge areas have different internal resistance values.

7. The plasma processing apparatus of claim 6, wherein the first electrode further includes at least one intermediate area interposed between the central area and the edge area, and the respective central area, edge area, and intermediate area have different internal resistance values.

8. The plasma processing apparatus of claim 1, wherein the first electrode includes a plurality of plates having a central area, an edge area, and at least one intermediate area interposed therebetween.

9. The plasma processing apparatus of claim 1, wherein the first electrode comprises:
an upper plate for receiving a radio frequency from the power source; and
a lower plate on below the upper plate for positioning a substrate.

10. The plasma processing apparatus of claim 9, wherein at least one of the lower plate and the upper plate is made of silicon.

11. The plasma processing apparatus of claim 1, wherein the first electrode includes a plurality of gas distribution openings for distributing an etch gas.

12. A method for producing a plasma processing apparatus comprising:
providing a chamber for loading a substrate therein;
installing first and second electrodes in the chamber; and
affixing a power source for supplying a radio frequency to the first electrode,
wherein the first electrode includes a plurality of areas having different internal resistances.

13. The method of claim 12, wherein the first electrode has a central area and an edge area, and the respective central area and edge areas have different internal resistance values.

14. The method of claim 13, wherein the resistance value of the central area is lower than that of the edge area.

15. The method of claim 12, wherein the first electrode further includes at least one intermediate area interposed between the central area and the edge area, and the respective central area, edge area, and intermediate area have different internal resistance values.

16. The method of claim 12, wherein the first electrode forms said different internal resistances at the respective areas by implanting a different amount of ions into the respective areas.

17. The method of claim 16, wherein the first electrode has a central area and an edge area, and the respective central area and edge areas have different internal resistance values.

18. The method of claim 17, wherein the first electrode further includes at least one intermediate area interposed between the central area and the edge area, and the respective central area, edge area, and intermediate area have different internal resistance values.

19. The method of claim 12, wherein the first electrode includes a plurality of plates having a central area, an edge area, and at least one intermediate area interposed therebetween.

20. The method of claim 12, wherein the first electrode comprises:
an upper plate for receiving a radio frequency from the power source; and
a lower plate on below the upper plate on which a substrate is located.

21. The method of claim 20, wherein at least one of the lower plate and the upper plate is made of silicon.

22. The method of claim 12, wherein the first electrode includes a plurality of gas distribution openings for distributing an etch gas.
